(19) United States
(12) Patent Application Publication
(10) Pub. No.: US 2012/0298996 A1
(43) Pub. Date: Nov. 29, 2012

(54) Thin Film Transistor and Method for Manufacturing the Same

(75) Inventors: Chin-Tzu Kao, Changhua County (TW); Kuo-Wei Wu, New Taipei City (TW); Chong-Ming Yang, Taoyuan City (TW)

(73) Assignee: CHUNGHWA PICTURE TUBES, LTD., Bade City (TW)

(21) Appl. No.: 13/291,150

(22) Filed: Nov. 8, 2011

(30) Foreign Application Priority Data
May 26, 2011 (TW) 100118488

(51) Int. Cl. H01L 29/786; H01L 21/336

(52) U.S. Cl. 257/57; 438/158; 257/E21.411; 257/E29.273

(57) ABSTRACT

A thin film transistor and a method for manufacturing the same are provided. A photoresist layer is patterned to cover a part of an ohmic contact layer by shifting a photomask. Then, the exposed ohmic contact layer is removed to shorten the channel length of the thin film transistor for increasing on-state current.

### RELATED APPLICATIONS

This application claims priority to Taiwan Application Serial Number 100118488, filed May 26, 2011, which is herein incorporated by reference.

### BACKGROUND

1. Field of Invention

The present invention relates to a thin film transistor and a method for manufacturing the same. More particularly, the present invention relates to a thin film transistor for liquid crystal display devices and a method for manufacturing the thin film transistor.

2. Description of Related Art

A liquid crystal display device primarily includes components of a thin film transistor, a color filter and liquid crystal etc. The thin film transistor primarily includes a gate electrode, a gate dielectric layer, a source electrode, and a drain electrode. When an external voltage is applied to the gate electrode, an ohmic contact layer, which is closed to the gate dielectric layer, is induced to form a channel between the source electrode and the drain electrode. Generally, the channel length may influence an on-state current. Therefore, the channel length may be shortened to increase the on-state current.

The method for manufacturing the thin film transistor generally includes several photolithographic and etching processes for forming the components described above. However, the shortest channel length can be only about 3-4 μm due to limitations in the accuracy of exposing apparatuses. Therefore, the on-state current of the thin film transistor is restricted.

### SUMMARY

The following presents a summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

An aspect of this invention provides a method of patterning photoresist layer to cover a part of ohmic contact layer by shifting a photomask. Then, the exposed ohmic contact layer is removed to shorten the channel length of the thin film transistor for increasing on-state current.

According to one embodiment of this invention, a method for manufacturing a thin film transistor including following steps is provided. A thin film transistor is formed on a substrate. The thin film transistor includes a gate electrode, a gate dielectric layer, a channel layer, an ohmic contact layer, a source electrode, and a drain electrode. Then, a photoresist layer is formed on the thin film transistor. A photomask for patterning the source electrode and the drain electrode is then shifted toward the source electrode or the drain electrode. A shift distance is less than the distance between the source electrode and drain electrode. Afterwards, the photoresist layer is patterned to expose a part of the ohmic contact layer. The exposed part of the ohmic contact layer is then removed to form an opening. The distance between the source electrode and drain electrode can be greater than the width of the opening. The opening width may be about 2-3 μm.

According to another embodiment of this invention, a thin film transistor is provided, which includes a substrate, a gate electrode disposed on the substrate, a gate dielectric layer disposed on the gate electrode, a channel layer disposed on the gate dielectric layer, an ohmic contact layer disposed on the channel layer, and source electrode and drain electrode disposed on opposite sides of the ohmic contact layer and on the gate dielectric layer. The ohmic contact layer has an opening located between the source electrode and the drain electrode. A distance between the source electrode and the drain electrode can be greater than a width of the opening. In addition, the thin film transistor can further include a passivation layer and a pixel electrode.

It is to be understood that both the foregoing general description and the following detailed description are by examples, and are intended to provide further explanation of the invention as claimed.

### BRIEF DESCRIPTION OF THE DRAWINGS

The invention may be more fully understood by reading the following detailed description of the embodiment, with reference made to the accompanying drawings as follows:

FIG. 1A to FIG. 1D are sectional schematic diagrams of a fabrication method of a thin film transistor according to one embodiment of this invention; and

FIG. 2 is a sectional schematic diagram of a thin film transistor according to another embodiment of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As described above, a photoresist layer is patterned to cover a part of an ohmic contact layer by shifting a photomask. Then, the exposed ohmic contact layer is removed to shorten the channel length of the thin film transistor.

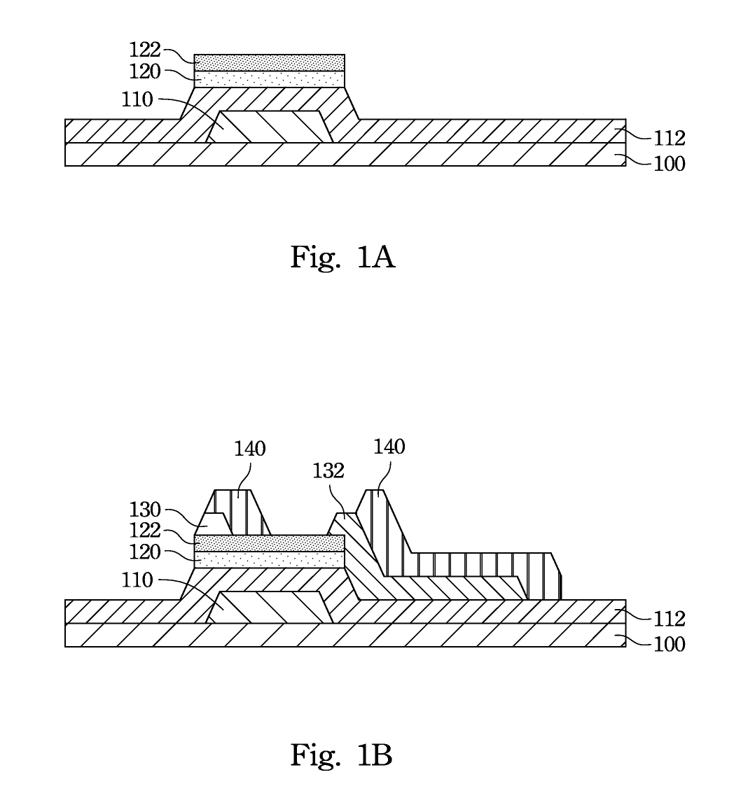

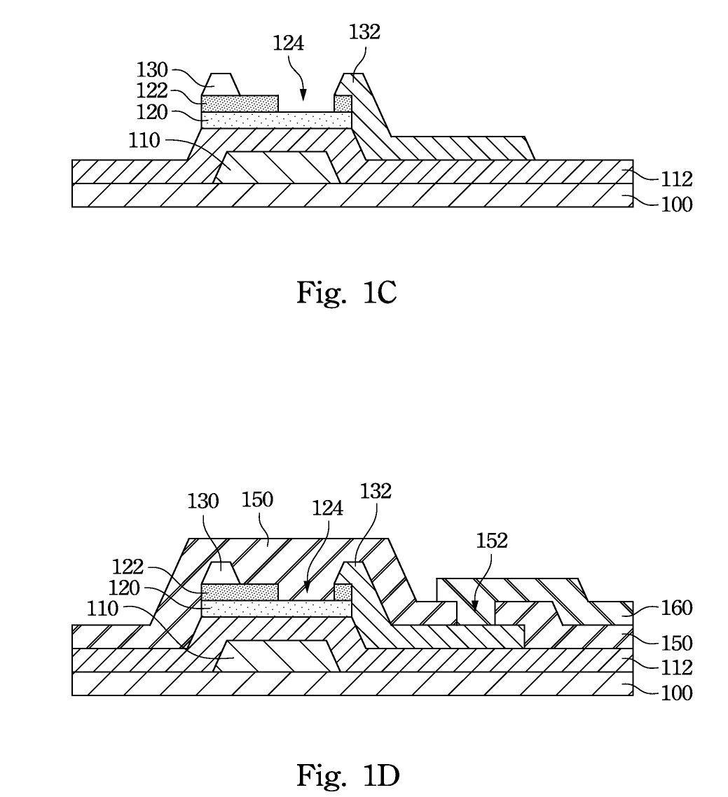

The method for manufacturing the thin film transistor is described below in detail. FIG. 1A to FIG. 1D are sectional schematic diagrams of a fabrication method of a thin film transistor according to one embodiment of this invention.

As shown in FIG. 1A, a gate electrode 110, a gate dielectric layer 112, a channel layer 120, and an ohmic contact layer 122 are formed on a substrate 100 in sequence. The gate electrode 110 can be made of aluminum, copper or other suitable conductive materials. As an example, a conductive layer is deposited on the substrate 100, and a photolithographic etching process is performed to form the gate electrode 110. The gate dielectric layer 112 can be made of silicon dioxide or silicon nitride. As an example, an amorphous silicon layer is deposited on the gate dielectric layer 112 and then doped with some carriers, and a photolithographic etching process is further performed to form the channel layer 120 and the ohmic contact layer 122.

As shown in FIG. 1B, a source electrode 130 and a drain electrode 132 are formed on the ohmic contact layer 122 and the gate dielectric layer 112. The source electrode 130 and the drain electrode 132 can be made of aluminum, copper or other suitable conductive materials. As an example, a conductive layer is deposited on the ohmic contact layer 122 and the gate dielectric layer 112, and a photolithographic etching process is further performed to form the source electrode 130 and the drain electrode 132. Specifically, the distance between the source electrode 130 and the drain electrode 132 is depended on the accuracy of exposing apparatuses used in the photolithographic process, therefore the distance between the source electrode 130 and the drain electrode 132 is about 3-4 μm.

A patterned photoresist layer 140 is then formed on the ohmic contact layer 122, the source electrode 130, and the drain electrode 132 to cover a part of the ohmic contact layer 122. The method for forming the patterned photoresist layer 140 includes following steps. A photoresist layer is formed, and a photolithographic process is performed after shifting the photomask, which is used for patterning the source electrode 130 and the drain electrode 132, toward the drain electrode 132 for a suitable distance. Therefore, a part of the ohmic contact layer 122 is covered with the remaining photoresist layer 140, and the other part of the ohmic contact layer 122 is kept exposed. Thus, the length of the exposed ohmic contact layer 122 may be shortened. Specifically, the length of the ohmic contact layer 122 covered with the phororesist layer 140 is about 1 μm.

As shown in FIG. 1C, the exposed ohmic contact layer 122 is removed to form an opening 124, and the opening 124 can be used to electrically isolate the source electrode 130 and the drain electrode 132. The ohmic contact layer 122 may be removed by a dry etch process. Specifically, the channel length below the opening 124 is about 2-3 μm.

As shown in FIG. 1D, a passivation layer 150 is formed on the source electrode 130, the drain electrode 132, the ohmic contact layer 122, and the gate dielectric layer 112. A contact window 152 is formed in the passivation layer 150 to expose a part of the upper surface of the drain electrode 132. A pixel electrode 160 is then formed in the contact window 152 and on the passivation layer 150, such that the drain electrode 132 is electrically connected to the pixel electrode 160. The passivation layer 150 can be made of silicon dioxide or silicon nitride. The pixel electrode 160 can be made of a transparent conductive material, such as indium tin oxide.

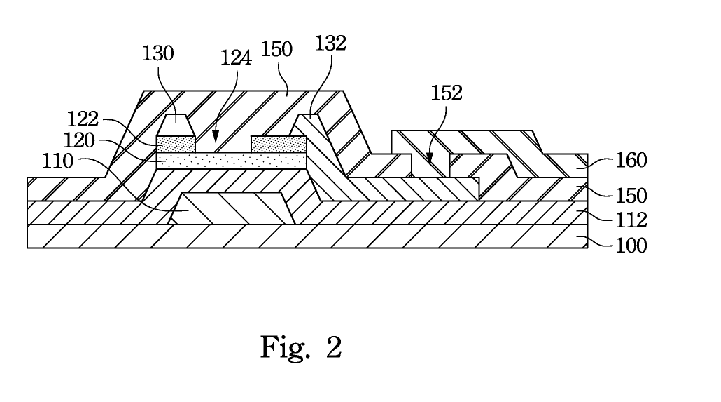

FIG. 2 is a sectional schematic diagram of the thin film transistor according to another embodiment of this invention. As shown in FIG. 2, the position of the opening 124 in the ohmic contact layer 122 is arranged near the source electrode 130. The method for forming this structure is described below. First, the structure as shown in FIG. 1A is formed. The source electrode 130 and the drain electrode 132 are then formed on the ohmic contact layer 122 and the gate dielectric layer 112. Then, the patterned photoresist layer 140 is formed by performing a photolithography and etching process after the photomask for patterning the source electrode 130 and the drain electrode 132 shifted toward the source electrode 130 to form the opening 124 near the source electrode 130. Then, the passivation layer 150 is formed on the source electrode 130, the drain electrode 132, the ohmic contact layer 122, and the gate dielectric layer 112. The contact window 152 is then formed in the passivation layer 150. Finally, the pixel electrode 160 is formed in the contact window 152.

The thin film transistor is described below in detail. As shown in FIGS. 1D and 2, the figures are sectional schematic diagrams of different embodiments of the thin film transistor of the invention. The thin film transistor includes the substrate 100, the gate electrode 110, the gate dielectric layer 112, the channel layer 120, the ohmic contact layer 122, the source electrode 130, and the drain electrode 132 in sequence. In addition, the thin film transistor may further include the passivation layer 150 and the pixel electrode 160.

The gate electrode 110 is disposed on the substrate 100. The substrate 100 can be made of glass or quartz. The gate electrode 110 can be made of aluminum, copper or other conductive materials.

The gate dielectric layer 112 is disposed on the gate electrode 110. The gate dielectric layer 112 can be made of silicon dioxide or silicon nitride.

The channel layer 120 and the ohmic contact layer 122 are disposed on the gate dielectric layer 112. The ohmic contact layer 122 has the opening 124.

The source electrode 130 and the drain electrode 132 are disposed on the ohmic contact layer 122. The source electrode 130 and the drain electrode 132 can be made of aluminum, copper or other suitable conductive materials. The opening 124 is disposed between the source electrode 130 and drain electrode 132. The distance between the source electrode 130 and the drain electrode 132 is greater than the width of the opening 124. One illustrative structure is shown in FIG. 1D, in which the opening 124 is arranged near the drain electrode 132, i.e., the distance between the opening 124 and the source electrode 130 is greater than the distance between the opening 124 and the drain electrode 132. Another illustrative structure is shown in FIG. 2, in which the opening 124 is arranged near the source electrode 130, i.e., the distance between the opening 124 and the source electrode 130 is less than the distance between the opening 124 and the drain electrode 132.

Moreover, the passivation layer 150 can be formed on the gate dielectric layer 112, the ohmic contact layer 122, the source electrode 130, and the drain electrode 132. The passivation layer 150 has the contact window 152. The passivation layer 150 can be made of silicon dioxide or silicon nitride. The pixel electrode 160 is then formed in the contact window 152 and on the passivation layer 150.

As described above, the photoresist layer is patterned to cover a part of the ohmic contact layer by shifting the photomask. Then, the exposed ohmic contact layer is removed to shorten the width of the opening. The width of the opening is equal to the channel length below the opening. The method for manufacturing the thin film transistor does not require additional photomasks since the photomask described above is the same photomask used for patterning the source and drain electrodes. Therefore, greater manufacturing efficiency may be realized without increasing manufacturing costs. Furthermore, when an external voltage is applied to the gate electrode, a shorter channel induced by the external voltage is formed to increase the on-state current of the thin film transistor.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims.

What is claimed is:

1. A method for manufacturing a thin film transistor comprising:
forming a thin film transistor on a substrate, the thin film transistor comprising a gate electrode, a gate dielectric layer, a channel layer, an ohmic contact layer, a source electrode, and a drain electrode;
forming a photoresist layer on the thin film transistor;
shifting the photomask for patterning the source electrode and the drain electrode toward the source electrode or the drain electrode, wherein a shift distance is less than a distance between the source electrode and the drain electrode;
patterning the photoresist layer to expose a part of the ohmic contact layer;
removing the exposed part of the ohmic contact layer to form an opening, wherein the distance between the source electrode and the drain electrode is greater than a width of the opening; and
removing the photoresist layer.

2. The method of claim 1, wherein the width of the opening is 2-3 μm.

3. The method of claim 1, further comprising:
forming a passivation layer on the gate dielectric layer, the ohmic contact layer, the source electrode, and the drain electrode; and
forming a contact window in the passivation layer to expose a part of the drain electrode; and
forming a pixel electrode in the contact window and on the passivation layer.

4. A thin film transistor comprising:
a substrate;
a gate electrode disposed on the substrate;
a gate dielectric layer disposed on the gate electrode;
a channel layer disposed on the gate dielectric layer;
an ohmic contact layer disposed on the channel layer, wherein the ohmic contact layer has an opening; and
a source electrode and a drain electrode disposed on opposite sides of the ohmic contact layer and on the gate dielectric layer, wherein the opening is located between the source electrode and the drain electrode, and a distance between the source and the drain electrode is greater than a width of the opening.

5. The thin film transistor of claim 4, wherein the width of the opening is 2-3 μm.

6. The thin film transistor of claim 4, wherein the distance between the opening and the source electrode is less than the distance between the opening and the drain electrode.

7. The thin film transistor of claim 4, wherein the distance between the opening and the source electrode is greater than the distance between the opening and the drain electrode.

8. The thin film transistor of claim 4, further comprising:
a passivation layer disposed on the gate dielectric layer, the ohmic contact layer, the source electrode, and the drain electrode, wherein the passivation layer has a contact window to expose a part of the drain electrode; and
a pixel electrode disposed in the contact window and on the passivation layer.
